(19) United States
(12) Patent Application Publication
(10) Pub. No.: US 2003/0203616 A1
(43) Pub. Date: Oct. 30, 2003

(54) Atomic layer deposition of tungsten barrier layers using tungsten carbonyls and boranes for copper metallization

(75) Inventors: Hua Chung, San Jose, CA (US); Seshadri Ganguli, Sunnyvale, CA (US); Ling Chen, Sunnyvale, CA (US)

Correspondence Address: APPLIED MATERIALS, INC., 2881 SCOTT BLVD. M/S 2061, SANTA CLARA, CA, 95050, US

(73) Assignee: Applied Materials, Inc.

(21) Appl. No.: 10/133,787

(22) Filed: Apr. 24, 2002

(51) Int. Cl. H01L 21/4763; H01L 21/44

(52) U.S. Cl. 438/627; 438/653; 438/656

(57) ABSTRACT

A method of tungsten layer deposition for copper metallization in semiconductor devices includes reacting a tungsten carbonyl compound and a borane compound using a cyclical deposition technique. In one embodiment, the tungsten barrier layer is formed on a patterned dielectric layer by alternately adsorbing the tungsten carbonyl compound and the borane compound onto a semiconductor substrate. The tungsten layers have substantially uniform dimensions and excellent adhesion to copper such as copper seed layers or direct electroplating of copper onto the tungsten layer.

### BACKGROUND OF THE DISCLOSURE

1. Field of the Invention

Embodiments described herein generally relate to cyclical deposition techniques for semiconductor processing.

2. Description of the Related Art

Semiconductor device geometries have dramatically decreased in size since such devices were first introduced several decades ago. Since then, integrated circuits have generally followed the two year/half-size rule (often called Moore's Law), which means that the number of devices that will fit on a chip doubles every two years. Today's fabrication plants are routinely producing devices having 0.35 μm and even 0.18 μm feature sizes, and tomorrow's plants soon will be producing devices having even smaller geometries.

Conductive materials having a low resistivity include copper and its alloys, which have become the materials of choice for sub-quarter-micron interconnect technology because copper has a lower resistivity than aluminum, (1.7 μΩ-cm compared to 3.1 μΩ-cm for aluminum), a higher current and higher carrying capacity. These characteristics are important for supporting the higher current densities experienced at high levels of integration and increased device speed. Further, copper has a good thermal conductivity and is available in a highly pure state.

One difficulty in using copper in semiconductor devices is that a barrier layer such as tungsten is typically required to prevent migration of copper into surrounding materials, such as dielectric materials. However, barrier layers also contribute undesirable properties, and are deposited in amounts greater than needed since conventional barrier layers have a substantially varying thickness. Commercially available tungsten layers contain impurities that can reduce adhesion of the tungsten layer to copper or reduce the conductivity of copper in semiconductor devices. Therefore, new methods of tungsten deposition are being developed.

### SUMMARY OF THE INVENTION

A method of tungsten layer deposition for copper metallization in semiconductor devices is described herein. Copper metallization typically includes copper lines separated from a dielectric material by a barrier layer. For some embodiments, the barrier layer comprises tungsten having reduced impurities that impair adhesion to copper or impair the conductivity of copper. In one embodiment, reduced impurities results from reacting tungsten precursors with a borane compound using a cyclical deposition technique. The tungsten is formed by alternately adsorbing the tungsten precursor and the borane compound on a substrate. The tungsten layers may contain boron impurities that do not impair adhesion to copper or conductivity of copper. The tungsten layers also have substantially uniform dimensions and can be deposited at any desired thickness to minimize the amount of barrier layer material.

In one embodiment, the tungsten layer of the present invention is deposited by the cyclical deposition technique using a tungsten carbonyl compound and a borane compound to provide a tungsten layer that may contain carbon, oxygen, and boron constituents. A copper layer is then deposited on the tungsten layer. The tungsten layer adheres well to copper deposited by electrochemical deposition and does not require a copper seed layer although a seed layer can be used.

### BRIEF DESCRIPTION OF THE DRAWINGS

So that the manner in which the above recited features of the present inventions are attained and can be understood in detail, a more particular description of the inventions, briefly summarized above, may be had by reference to the embodiments illustrated in the appended drawings. The appended drawings illustrate only typical embodiments of the inventions, and are therefore not to be considered limiting of its scope, for the inventions may admit to other equally effective embodiments.

FIG. 1 depicts a schematic partial cross-sectional view of a process chamber that may be used for the practice of embodiments described herein;

FIG. 2 illustrates a process sequence for the formation of a tungsten-containing material using cyclical deposition techniques according to one embodiment described herein;

FIG. 3 illustrates a process sequence for the formation of a tungsten-containing material using cyclical deposition techniques according to a another embodiment described herein; and

FIGS. 4A-4D depict cross-sectional views of substrates at different stages of a copper metallization sequence of the present invention.

### DETAILED DESCRIPTION

An embodiment of the present invention is described below in reference to a method of copper metallization that includes depositing a tungsten layer in a cyclical deposition chamber such as the chamber described in U.S. patent application Ser. No. 10/032,284, entitled “Gas Delivery Apparatus and Method For Atomic Layer Deposition”, filed on Dec. 21, 2001, which is incorporated herein by reference herein to the extent not inconsistent with the claimed aspects and description herein. A brief description of the processing chamber follows. Another suitable processing chamber for performing the processes described herein is described in commonly assigned U.S. patent application Ser. No. 10/016,300, filed on Dec. 12, 2001, which is incorporated herein by reference. Both processing chambers are available from Applied Materials, Inc. located in Santa Clara, Calif.

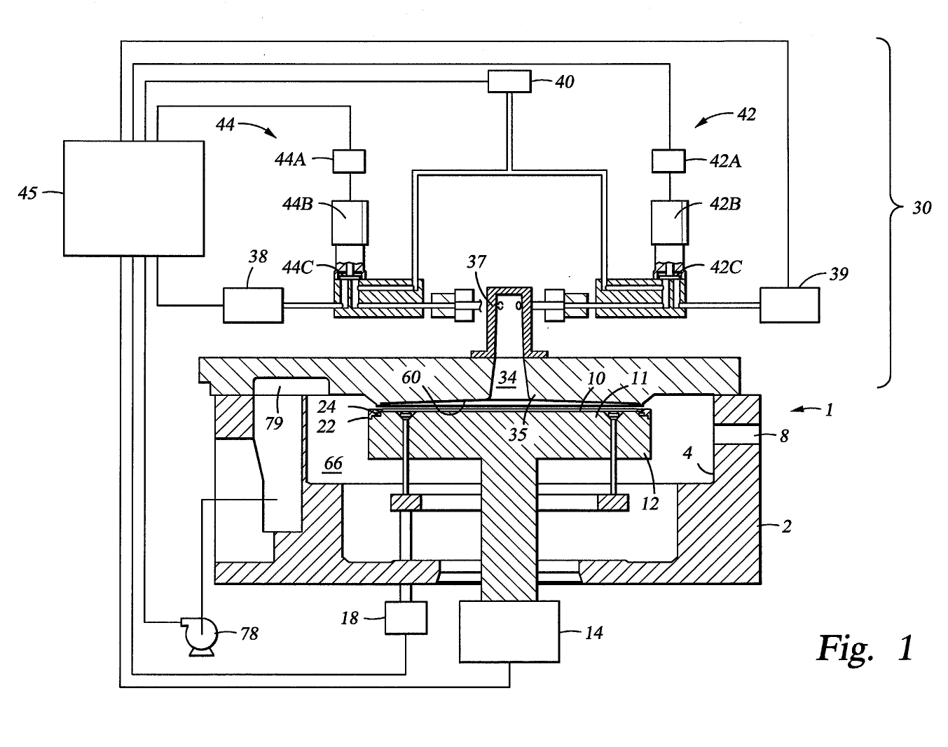

FIG. 1 illustrates a schematic, partial cross section of an exemplary processing chamber 1 for use in a method of forming a barrier layer according to each of the embodiments of the present invention. The processing chamber 1 may be integrated into an integrated processing platform, such as an Endura™ platform also available from Applied Materials, Inc. Details of the Endura™ platform are described in commonly assigned U.S. patent application Ser. No. 09/451,628, entitled “Integrated Modular Processing Platform”, filed on Nov. 30, 1999, which is incorporated by reference herein. Additional chambers that may be integrated into the integrated processing platform include degas chambers and pre-clean chambers which are also available from by Applied Materials.

Referring to FIG. 1, the processing chamber 1 includes a chamber body 2 having a slit valve 8 formed in a sidewall 4 thereof and a substrate support 12 disposed therein. The substrate support 12 is mounted to a lift motor 14 to raise and lower the substrate support 12 and a substrate 10 disposed thereon. The substrate support 12 may also include wafer lifting means 18 for raising and lowering the substrate onto the substrate support 12. A purge ring 22 may be disposed on the substrate support 12 to define a purge channel 24 which provides a purge gas to prevent deposition on a peripheral portion of the substrate 10.

A gas delivery apparatus 30 is disposed at an upper portion of the chamber body 2 to provide a gas, such as a process gas and/or a purge gas, to the chamber 1. A vacuum system 78 is in communication with a pumping channel 79 to evacuate gases from the chamber 1 and to help maintain a desired pressure or a desired pressure range inside a pumping zone 66 of the chamber 1. Additional components (not shown) for delivery of solid precursors such as tungsten hexacarbonyl to the gas delivery apparatus 30 may be used, such as the sublimation device described in U.S. patent application Ser. No. 20020009544, which published on Jan. 24, 2002.

The gas delivery apparatus 30 includes a chamber lid 35 having an expanding channel 34 formed within a central portion thereof. The chamber lid 35 also includes a bottom surface 60 extending from the expanding channel 34 to a peripheral portion of the chamber lid 35. The bottom surface 60 is sized to substantially cover the substrate 10 disposed on the substrate support 12. The expanding channel 34 has an inner diameter that gradually increases from an upper portion 37 to the bottom surface 60 of the chamber lid 35. The velocity of a gas flowing therethrough decreases as the gas flows through the expanding channel 34 due to the expansion of the gas. The decreased gas velocity reduces the likelihood of blowing off reactants adsorbed on the surface of the substrate 10. Gas sources 38, 39, 40 provide gases, such as the tantalum precursor and borane gases to the chamber 1 during operation.

The gas delivery apparatus 30 also includes at least two high speed actuating valve assemblies 42, 44. At least one valve assembly 42, 44 is dedicated to each reactive compound. For example, a first valve assembly is dedicated to a tantalum carbonyl compound, such as tantalum hexacarbonyl, and a second valve assembly is dedicated to a borane compound, such as diborane.

Each valve assembly 42, 44 includes a control valve 42A, 44A that signals an actuator body 42B, 44B to move a valve seat 42C, 44C such as a diaphragm or other pulsing means. The valve assemblies 42, 44 may include electronically controlled (EC) valves, which are commercially available from Fujikin of Japan as part number FR-21-6.35 UGF-APD. Each valve assembly 42, 44 precisely and repeatedly delivers short pulses of the reactive compound into the chamber body 2. The on/off cycles or pulses of each valve assembly 42, 44 is typically less than about 100 msec. The control valves 42A, 44A can be directly coordinated by a system computer 45, such as a mainframe for example, or coordinated by a chamber/application specific controller, such as a programmable logic computer (PLC) which is described in more detail in the co-pending U.S. patent application Ser. No. 09/800,881, entitled “Valve Control System For ALD Chamber”, filed on Mar. 7, 2001, which is incorporated by reference herein.

Software routines are executed to initiate process recipes or sequences. The software routines, when executed, transform the system computer 45 into a specific process computer that controls the chamber operation so that a chamber process is performed. For example, software routines may be used to precisely control the activation of the valve assemblies 42, 44 for the execution of process sequences according to the present invention. Alternatively, the software routines may be performed in hardware, as an application specific integrated circuit or other type of hardware implementation, or a combination of software or hardware.

Barrier Layer Formation

A method of tungsten deposition for barrier layer applications is described. The tungsten directly adheres to a dielectric layer such as parylene, silicon oxide, fluorine doped silicon oxide (e.g., FSG), spin on glass, SiLK™ silicon oxide, carbon doped silicon oxide (e.g., Black Diamond™ dielectric layers available from Applied Materials, Inc.), porous silicon oxides, or the like, when deposited using a cyclical deposition technique such as by alternately adsorbing one or more tungsten carbonyl compounds and one or more borane compounds on a dielectric layer. The cyclical deposition techniques employed for the tungsten deposition provides conformal coverage on planar structures or structures having aggressive geometries such as openings less than about 0.2 μm (micrometers) and/or aspect ratios greater than about 4:1. Examples of structures having such aggressive geometries include dual damascene dielectric layers patterned for simultaneous deposition of a barrier layer in trenches and vias. The cyclical deposition techniques are also effective for openings less than about 0.1 μm (micrometers) such as openings encountered in 100 nanometer and 70 nanometer design rules, and beyond.

Adhesion of the tungsten layer is enhanced when the dielectric layer is degassed to remove moisture, the dielectric layer is pre-cleaned in a Pre-Clean II chamber available from Applied Materials, Inc., and the tungsten carbonyl compound is absorbed first on the dielectric layer and then exposed to a greater than stoichiometric amount of the borane compound to complete the reaction. The tungsten layer may also be referred to as a tungsten boride layer if significant amounts of boron remain.

In an alternative embodiment (not shown), the tungsten layer is deposited on a thin adhesion layer that is deposited on the dielectric layer to further improve adhesion between the tungsten layer and the dielectric layer. In one aspect, the adhesion layer is less than 5 Å of titanium nitride (TiN) or titanium silicon nitride (TiNSi) layer. For example, a TDMAT precursor is used to deposit a TiN layer. The TiN layer may then be exposed to a silane-based material, such as SiH₄, to form the TiNSi layer.

The tungsten carbonyl compounds are selected from tungsten hexacarbonyl (W(CO)₆), tungsten pentacarbonyl compounds (RW(CO)₅), and tungsten tetracarbonyl compounds (R₂W(CO)₄) wherein R is one or more ligands replacing one or more carbonyl groups. Preferably each R is an alkylisonitrile group (R¹—N═C═) wherein each R¹ is an alkyl group having from 4 to 8 carbon atoms, such as n-butyl, 1-ethylpropyl, 1,2 dimethylpropyl, isopentyl, 2-methylbutyl, 1-methylbutyl, n-pentyl, 1,3-dimethylbutyl, n-hexyl, 1-methylhexyl, and n-octyl.

Suitable borane compounds include, for example, borane (BH₃), diborane(6) (B₂H₆), triborane(8) (B₃H₈), tetraborane(10) (B₄H₁₀), pentaborane(9) (B₅H₉), pentaborane(11) (B₅H₁₁), hexaborane(10) (B₆H₁₀), octaborane(10) (B₈H₁₀), octaborane(12) (B₈H₁₂), nonaborane(15) (B₉H₁₅), decaborane(14) (B₁₀H₁₄), and decaborane(16) (B₁₀H₁₆), among others, and combinations thereof. Preferably the borane compound is diborane(6).

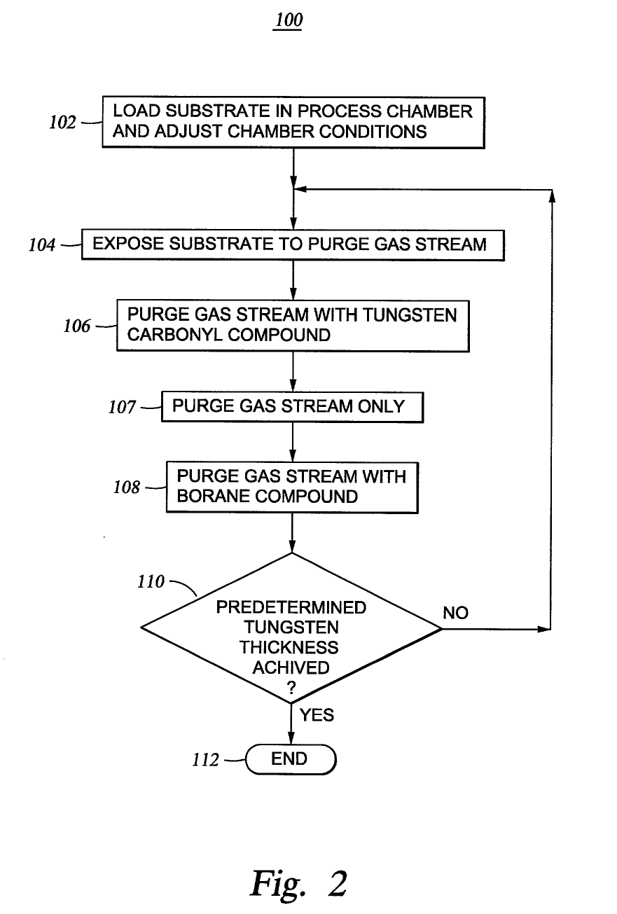

FIG. 2 illustrates an embodiment of a process sequence 100 according to the present invention comprising various steps used for the deposition of the tungsten layer utilizing a constant carrier gas flow. As shown in step 102, a substrate is provided to the process chamber. The process chamber conditions such as, for example, the temperature and pressure are adjusted to enhance the adsorption of the process gases on the substrate. In general, for tungsten deposition, the substrate should be maintained at a temperature between about 120° C. and about 400° C., preferably between about 200° C. and about 325° C., at a process chamber pressure of between about 1 torr and about 10 torr, preferably between 0.5 torr and about 4 torr.

In one embodiment where a constant carrier gas flow is desired, a carrier gas stream is established within the process chamber as indicated in step 104. Carrier gases may be selected to also act as a purge gas for removal of volatile reactants and/or by-products from the process chamber. Carrier gases, such as, for example, helium (He), argon (Ar), nitrogen (N₂) and hydrogen (H₂), and combinations thereof, among others may be used.

Referring to step 106, after the carrier gas stream is established within the process chamber, a pulse of a tungsten carbonyl compound is added to the carrier gas stream. The term pulse as used herein refers to a dose of material injected into the process chamber or into the constant carrier gas stream. The pulse of the tungsten carbonyl compound lasts for a predetermined time interval.

The time interval for the pulse of the tungsten carbonyl compound is variable depending upon a number of factors such as, for example, the volume capacity of the process chamber employed, the vacuum system coupled thereto and the volatility/reactivity of the reactants used. For example, (1) a large-volume process chamber may lead to a longer time to stabilize the process conditions such as, for example, carrier/purge gas flow and temperature requiring a longer pulse time; (2) a lower flow rate for the process gas may also lead to a longer time to stabilize the process conditions requiring a longer pulse time; and (3) a lower chamber pressure means that the process gas is evacuated from the process chamber more quickly requiring a longer pulse time. In general, the process conditions are advantageously selected so that a pulse of the tungsten carbonyl compound provides a sufficient amount of compound so that at least a monolayer of the tungsten carbonyl compound is adsorbed on the substrate.

In step 107, a purge gas comprising the carrier gas is provided to the process chamber in an amount from a brief pulse to flush excess tungsten carbonyl from where the borane compound will be injected to a longer pulse sufficient to remove excess tungsten carbonyl from the process chamber prior to further processing. For example, a brief pulse of the purge gas could move excess tungsten carbonyl toward the edges of a substrate prior to injecting the borane compound at the center of the substrate.

In step 108, a pulse of a borane compound is added to the carrier gas stream. The pulse of the borane compound also lasts for a predetermined time interval that is variable as described above with reference to the tungsten carbonyl compound. In general, the time interval for the pulse of the borane compound should be long enough for adsorption of at least a monolayer of the borane compound on the tungsten carbonyl compound. The amount of borane compound is preferably in excess of the amount required for complete conversion of the tungsten carbonyl compound to tungsten or tungsten with desired film properties, such as low film resistivity and low film impurities as compared to carbon containing tungsten films. In has been observed that the exposure time of borane compound and its flow rate depends on the film property desire. For example increase borane flow rate is believed to reduce carbonyl and carbon contaminants, lowering the film resistivity and improve barrier properties. Thereafter, excess borane compound remaining in the chamber after reaction with the tungsten carbonyl compound may be removed therefrom by the constant carrier gas stream in combination with the vacuum system.

Steps 104 through 108 comprise one embodiment of a deposition cycle for tungsten. For such an embodiment, a constant flow of the carrier gas is provided to the process chamber modulated by alternating periods of pulsing and non-pulsing where the periods of pulsing alternate between the tungsten carbonyl compound and the borane compound along with the carrier gas stream, while the periods of non-pulsing include only the carrier gas stream.

The time interval for each of the pulses of the tungsten carbonyl compound and each of the pulse of the borane compound may have the same duration. That is, the duration of the pulse of the tungsten carbonyl compound is identical to the duration of the pulse of the borane compound. For such an embodiment, a time interval (T₁) for each of the pulses of the tungsten carbonyl compound is equal to a time interval (T₂) for each of the pulses of the borane compound.

Alternatively, the time interval for each of the pulses of the tungsten carbonyl compound and the borane compound may have different durations. That is the duration of the pulse of the tungsten carbonyl compound may be shorter or longer than the duration of the pulse of the borane compound. For such an embodiment, a time interval (T₁) for the pulse of the tungsten carbonyl compound is different than a time interval (T₂) for the pulse of the borane compound. The pulse may also change for a particular gas between cycles. For example, the tungsten pulse may increase or decrease with each cycle. The same can be true for the borane compound.

In addition, the periods of non-pulsing between each of the pulses of the tungsten carbonyl compound and the borane compound may have the same duration. That is the duration of the period of non-pulsing between each pulse of the tungsten carbonyl compound and each pulse of the borane compound is identical. For such an embodiment, a time interval (T₃) of non-pulsing between the pulse of the tungsten carbonyl compound and the pulse of the borane compound is equal to a time interval (T₄) of non-pulsing between the pulse of the borane compound and the pulse of the tungsten carbonyl compound. During the time periods of non-pulsing only the constant carrier gas stream is provided to the process chamber.

Alternatively, the periods of non-pulsing between each of the pulses of the tungsten carbonyl compound and the borane compound may have different durations. That is the duration of the period of non-pulsing between each pulse of the tungsten carbonyl compound and each pulse of the borane compound may be shorter or longer than the duration of the period of non-pulsing between each pulse of the borane compound and the tungsten carbonyl compound. For such an embodiment, a time interval (T₃) of non-pulsing between the pulse of the tungsten carbonyl compound and the pulse of the borane compound is different from a time interval (T₄) of non-pulsing between the pulse of the borane compound and the pulse of the tungsten carbonyl compound. During the time periods of non-pulsing only the constant carrier gas stream is provided to the process chamber.

Additionally, the time intervals for each pulse of the tungsten carbonyl compound, the borane compound, and the periods of non-pulsing therebetween for each deposition cycle may have the same duration. For such an embodiment, a time interval (T₁) for the tungsten carbonyl compound, a time interval (T₂) for the borane compound, a time interval (T₃) of non-pulsing between the pulse of the tungsten carbonyl compound and the pulse of the borane compound and a time interval (T₄) of non-pulsing between the pulse of the borane compound and the pulse of the tungsten carbonyl compound each have the same value for each deposition cycle. For example, in a first deposition cycle (C₁), a time interval (T₁) for the pulse of the tungsten carbonyl compound has the same duration as the time interval (T₁) for the pulse of the tungsten carbonyl compound in a second deposition cycle (C₂). Similarly, the duration of each pulse of the borane compound and the periods of non-pulsing between the pulse of the tungsten carbonyl compound and the borane compound in deposition cycle (C₁) is the same as the duration of each pulse of the borane compound and the periods of non-pulsing between the pulse of the tungsten carbonyl compound and the borane compound in deposition cycle (C₂), respectively.

Additionally, the time intervals for at least one pulse of the tungsten carbonyl compound, the borane compound, and the periods of non-pulsing therebetween for one or more of the deposition cycles of the tungsten deposition process may have different durations. For such an embodiment, one or more of the time intervals (T₁) for the pulses of the tungsten carbonyl compound, the time intervals (T₂) for the pulses of the borane compound, the time intervals (T₃) of non-pulsing between the pulse of the tungsten carbonyl compound and the pulse of the borane compound, and the time intervals (T₄) of non-pulsing between the pulse of the borane compound and the pulse of the tungsten carbonyl compound may have different values for one or more deposition cycles of the tungsten deposition process. For example, in a first deposition cycle (C₁), the time interval (T₁) for the pulse of the tungsten carbonyl compound may be longer or shorter than the time interval (T₁) for the pulse of the tungsten carbonyl compound in a second deposition cycle (C₂). Similarly, the duration of each pulse of the borane compound and the periods of non-pulsing between the pulse of the tungsten carbonyl compound and the borane compound in deposition cycle (C₁) may be the same or different than the duration of each pulse of the borane compound and the periods of non-pulsing between the pulse of the tungsten carbonyl compound and the borane compound in deposition cycle (C₂), respectively.

Referring to step 110, after each deposition cycle (steps 104 through 108) a thickness of tungsten will be formed on the substrate. Depending on specific device requirements, subsequent deposition cycles may be needed to achieve a desired thickness. As such, steps 104 through 108 are repeated until the desired thickness for the tungsten layer is achieved. Thereafter, when the desired thickness for the tungsten layer is achieved the process is stopped as indicated by step 112.

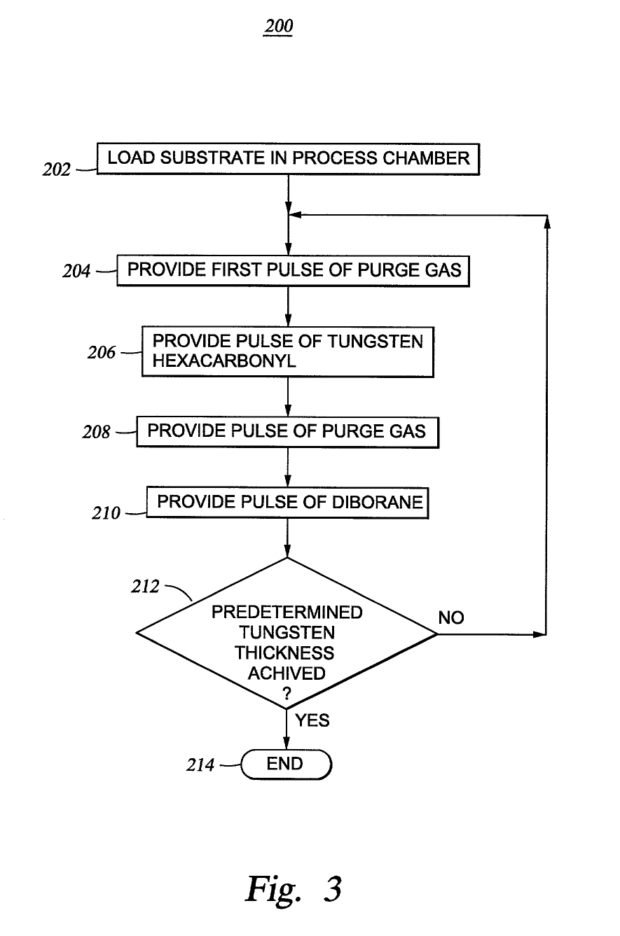

In another process sequence described with respect to FIG. 3, the tungsten deposition cycle comprises separate pulses for each of tungsten hexacarbonyl, diborane, and the purge gas to deposit a tungsten layer. For such an embodiment, a tungsten deposition sequence 200 includes providing a substrate to the process chamber (step 202), providing a first pulse of a purge gas to the process chamber (step 204), providing a pulse of the tungsten hexacarbonyl to the process chamber (step 206), providing a second pulse of the purge gas to the process chamber (step 208), providing a pulse of the diborane to the process chamber (step 210), and then repeating steps 204 through 208 or stopping the deposition process (step 214) depending on whether a desired thickness for the tungsten layer has been achieved.

The time intervals for each of the pulses of the tungsten hexacarbonyl, the diborane, and the purge gas may have the same or different durations as discussed above with respect to FIG. 2. Alternatively, the time intervals for at least one pulse of the tungsten hexacarbonyl, the purge gas for one or more of the deposition cycles of the tungsten deposition process may have different durations.

In FIGS. 2-3, the tungsten deposition cycle is depicted as beginning with a pulse of the tungsten carbonyl compound followed by a pulse of the borane compound. Alternatively, the tungsten deposition cycle may start with a pulse of the borane compound followed by a pulse of the tungsten carbonyl compound.

The tungsten hexacarbonyl may be provided to an appropriate flow control valve, for example, an electronic control valve, at a flow rate of between about 10 sccm (standard cubic centimeters per minute) and about 400 sccm, preferably between about 20 sccm and about 100 sccm, and thereafter pulsed for about 2 seconds or less, preferably about 0.2 seconds or less. A carrier gas comprising argon is provided along with the tungsten precursor at a flow rate between about 150 sccm to about 2000 sccm, preferably between about 500 sccm to about 750 sccm. The diborane (B₂H₆) may be provided to an appropriate flow control valve, for example, an electronic control valve, at a flow rate of between about 5 sccm and about 150 sccm, preferably between about 5 sccm and about 50 sccm, and thereafter pulsed for about 2 seconds or less, preferably about 0.2 seconds or less. A carrier gas comprising argon is provided along with the diborane at a flow rate between about 250 sccm to about 1000 sccm, preferably between about 500 sccm to about 750 sccm. The substrate may be maintained at a temperature between about 150° C. to about 350° C. at a chamber pressure between about 0.5 torr to about 10 torr. The flow rates of the gases can be adjusted between cycles so that one or more gas flows can be increased or descreased as deposition proceeds.

### HYPOTHETICAL EXAMPLE

A tungsten layer having excellent barrier properties and excellent adhesion to dielectric layers is deposited in the chamber of FIG. 1 with a heater temperature of 250° C. at 0.7 torr by flowing tungsten hexacarbonyl at 15 sccm and argon at 250 sccm for 0.5 seconds, flowing argon alone at 1000 sccm for 1 second, flowing diborane at 25 sccm and argon at 500 sccm for 1 second, and then flowing argon alone at 1000 sccm for 1 second. Repetition of these steps for 30 cycles deposits a tungsten layer having a thickness of about 30 Å.

Copper Metallization

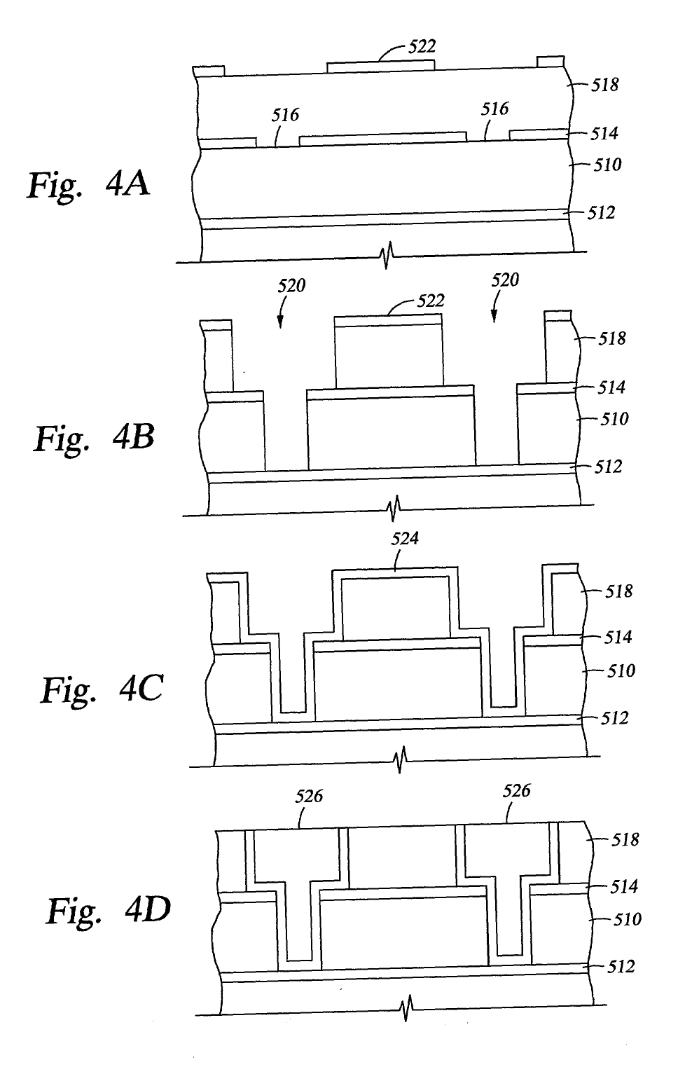

As shown in FIG. 4A, a first dielectric layer 510, such as parylene, silicon oxide, fluorine doped silicon oxide (e.g., FSG), spin on glass, carbon doped silicon oxide (e.g., Black Diamond™ silicon oxide available from Applied Materials, Inc.), SiLK™ silicon oxide, or the like, is deposited on a substrate 512. The thickness of the first dielectric layer 510 and subsequent layers described below will vary based on the design rule used to control the deposition process. For example, a thickness of about 5,000 to about 10,000 Å is suitable for formation of 0.13 μm design rule features depending on the size of the structure to be fabricated. A 100 nanometer or smaller design rule would correspond to a thickness less than 100 Å for the first dielectric layer 510. A 0.13 μm design rule is assumed for description of subsequent layers.

An etch stop 514, such as silicon carbide, silicon nitride, or the like is deposited on the first dielectric layer 510 to a thickness of about 200 to about 1000 Å. The etch stop 514 is pattern etched to define the contact/via openings 516 and to expose first dielectric layer 510 in the areas where the contacts/vias are to be formed. After etch stop 514 has been etched to pattern the contacts/vias and the photo resist has been removed, a second dielectric layer 518 is deposited over etch stop 514 to a thickness of about 5,000 to about 10,000 Å. The second dielectric layer 518 is patterned to define trenches, preferably using conventional photolithography processes with a photo resist layer 522. The trenches and contacts/vias 520 are then etched using reactive ion etching or other anisotropic etching techniques to define the metallization structure (Le., the interconnect and contact/via) as shown in FIG. 4B. Any photo resist or other material used to pattern the etch stop 514 or the second dielectric layer 518 is removed using an oxygen strip or other suitable process.

As shown in FIG. 4C, a suitable tungsten barrier layer 524 is first deposited in the metallization pattern at a thickness between about 5 Å and about 1000 Å, such as between about 5 Å to about 100 Å using the deposition sequence of the present invention to prevent copper migration into the surrounding silicon and/or dielectric material. Thereafter, copper 526 is deposited and planarized to form the conductive structure, as shown in FIG. 4D. Copper may be deposited on the tungsten layer by PVD, CVD, electroplating, or combinations thereof. Although copper is typically deposited on tungsten by depositing a seed layer using PVD or CVD and then electroplating the copper thereon, copper can be directly deposited on the tungsten by electroplating when the tungsten is deposited as described herein.

While foregoing is directed to the preferred embodiment of the present invention, other and further embodiments of the invention may be devised without departing from the basic scope thereof, and the scope thereof is determined by the claims that follow.

What is claimed is:

1. A method of copper metallization, comprising:
depositing a tungsten layer on a semiconductor substrate using a cyclical deposition process; and
depositing copper on the tungsten layer.

2. The method of claim 1, wherein the cyclical deposition process comprises alternately adsorbing monolayers of a tungsten carbonyl compound and a borane compound on the substrate.

3. The method of claim 2, wherein the tungsten carbonyl compound is selected from tungsten hexacarbonyl (W(CO)₆), tungsten pentacarbonyl compounds (RW(CO)₅), and tungsten tetracarbonyl compounds (R₂W(CO)₄), wherein R is one or more ligands replacing one or more carbonyl groups.

4. The method of claim 3, wherein each R is an alkylisonitrile group (R¹—N═C═), wherein each R¹ is an alkyl group having from 4 to 8 carbon atoms.

5. The method of claim 3, wherein each R is an alkylisonitrile group (R¹—N═C═), wherein each R¹ is n-butyl, 1-ethylpropyl, 1,2-dimethylpropyl, isopentyl, 2-methylbutyl, 1-methylbutyl, n-pentyl, 1,3-dimethylbutyl, n-hexyl, 1-methylhexyl, or n-octyl.

6. The method of claim 2, wherein the tungsten carbonyl compound is tungsten hexacarbonyl.

7. The method of claim 2, wherein the borane compound is selected from the group of borane, diborane(6), triborane(8), tetraborane(10), pentaborane(9), pentaborane(11), hexaborane(10), octaborane(10), octaborane(12), nonaborane(15), decaborane(14), decaborane(16), and combinations thereof.

8. The method of claim 7, wherein the borane compound is diborane.

9. The method of claim 1, wherein the copper is deposited by electroplating.

10. The method of claim 1, wherein the copper is deposited as a seed layer by CVD or PVD.

11. The method of claim 10, wherein additional copper is electroplated onto the seed layer.

12. The method of claim 2, wherein the cyclical deposition process comprises a plurality of cycles, wherein each cycle comprises establishing a flow of a purge gas to the process chamber and modulating the flow of the purge gas with an alternating period of exposure to one of either the tungsten carbonyl compound or the borane compound.

13. The method of claim 12, wherein the period of exposure to the tungsten carbonyl compound, the period of exposure to the borane compound, a period of flow of the purge gas between the period of exposure to the tungsten carbonyl compound and the period of exposure to the borane compound, and a period of flow of the purge gas between the period of exposure to the borane compound and the period of exposure to the tungsten carbonyl compound are adjusted to expose the tungsten carbonyl compound to excess borane compound.

14. The method of claim 13, wherein excess tungsten carbonyl and excess borane compound are substantially purged by the purge gas.

15. A method of copper metallization, comprising:
depositing a tungsten layer on a patterned dielectric layer by alternately adsorbing monolayers of tungsten hexacarbonyl and diborane; and
depositing copper on the tungsten layer.

16. The method of claim 15, wherein the copper is deposited by electroplating.

17. The method of claim 15, wherein the method comprises a plurality of cycles, wherein each cycle comprises establishing a flow of a purge gas to a process chamber and modulating the flow of the purge gas with an alternating period of exposure to the tungsten hexacarbonyl or the diborane.

18. The method of claim 17, wherein the period of exposure to the tungsten hexacarbonyl, the period of exposure to the diborane, a period of flow of the purge gas between the period of exposure to the tungsten hexacarbonyl and the period of exposure to the diborane, and a period of flow of the purge gas between the period of exposure to the diborane and the period of exposure to the tungsten hexacarbonyl are adjusted to expose absorbed tungsten hexacarbonyl to excess diborane.

19. A method of copper metallization, comprising:
depositing a tungsten layer on a semiconductor substrate by alternately adsorbing a monolayer of tungsten hexacarbonyl, purging excess tungsten hexacarbonyl, absorbing a monolayer of excess diborane, and purging excess diborane; and
electroplating copper on the tungsten barrier layer.

20. The method of claim 19, wherein the purge gas is adjusted to expose the tungsten hexacarbonyl to excess diborane

21. A semiconductor device having a copper metallization structure, comprising:
a tungsten layer deposited on a patterned dielectric layer by alternately adsorbing monolayers of tungsten hexacarbonyl and diborane; and
a copper layer deposited on the tungsten layer.

22. The semiconductor device of claim 21, wherein the copper is deposited by electroplating.

23. The semiconductor device of claim 22, wherein the tungsten layer is deposited by a plurality of cycles, wherein each cycle comprises establishing a flow of a purge gas to a process chamber and modulating the flow of the purge gas with an alternating period of exposure to the tungsten hexacarbonyl or the diborane.

24. The semiconductor device of claim 23, wherein the period of exposure to the tungsten hexacarbonyl, the period of exposure to the diborane, a period of flow of the purge gas between the period of exposure to the tungsten hexacarbonyl and the period of exposure to the diborane, and a period of flow of the purge gas between the period of exposure to the diborane and the period of exposure to the tungsten hexacarbonyl are adjusted to expose absorbed tungsten hexacarbonyl to excess diborane.

25. A method for depositing tungsten on a substrate, comprising a plurality of cycles, wherein each cycle comprises establishing a flow of a purge gas to the process chamber and modulating the flow of the purge gas with alternating periods of exposure to a tungsten carbonyl compound and a borane compound.

26. The method of claim 25, wherein the tungsten carbonyl compound is selected from tungsten hexacarbonyl (W(CO)₆), tungsten pentacarbonyl compounds (RW(CO)₅), and tungsten tetracarbonyl compounds (R₂W(CO)₄), wherein R is one or more ligands replacing one or more carbonyl groups.

27. The method of claim 26, wherein each R is an alkylisonitrile group (R¹—N═C═), wherein each R¹ is an alkyl group having from 4 to 8 carbon atoms.

28. The method of claim 26, wherein each R is an alkylisonitrile group (R¹—N═C═), wherein each R¹ is n-butyl, 1-ethylpropyl, 1,2-dimethylpropyl, isopentyl, 2-methylbutyl, 1-methylbutyl, n-pentyl, 1,3-dimethylbutyl, n-hexyl, 1-methylhexyl, or n-octyl.

29. The method of claim 26, wherein the tungsten carbonyl compound is tungsten hexacarbonyl.

30. The method of claim 25, wherein the borane compound is selected from the group of borane, diborane(6), triborane(8), tetraborane(10), pentaborane(9), pentaborane(11), hexaborane(10), octaborane(10), octaborane(12), nonaborane(15), decaborane(14), decaborane(16), and combinations thereof.

31. The method of claim 25, wherein the borane compound is diborane.

32. The method of claim 25, wherein the period of exposure to the tungsten carbonyl compound, the period of exposure to the borane compound, a period of flow of the purge gas between the period of exposure to the tungsten carbonyl compound and the period of exposure to the borane compound, and a period of flow of the purge gas between the period of exposure to the borane compound and the period of exposure to the tungsten carbonyl compound are adjusted to expose absorbed tungsten carbonyl compound to excess borane compound.
